(19) United States
(12) Patent Application Publication
(10) Pub. No.: US 2017/0342550 A1
(43) Pub. Date: Nov. 30, 2017

(54) Method for controlled growth of carbon nanotubes in a vertically aligned array

(71) Applicant: National Technology & Engineering Solutions of Sandia, LLC, Albuquerque, NM (US)

(72) Inventors: Michael P. Siegal, Albuquerque, NM (US); Caitlin Rochford Friedman, Albuquerque, NM (US); William G. Yelton, Sandia Park, NM (US)

(21) Appl. No.: 15/603,161

(22) Filed: May 23, 2017

Related U.S. Application Data
(60) Provisional application No. 62/342,083, filed on May 26, 2016.

(51) Int. Cl. C23C 16/26; C23C 16/44; C25D 3/12; C25D 5/48; H01L 23/373; C25D 11/04; C25D 5/02; B82Y 40/00; B82Y 30/00; H01J 1/304

(52) U.S. Cl. CPC C23C 16/26; C25D 11/045; C23C 16/44; C25D 3/12; C25D 5/022; C25D 5/48; H01L 23/3738; B82Y 30/00; H01J 1/304; B82Y 40/00; Y10S 977/742; Y10S 977/833; Y10S 977/843

(57) ABSTRACT

Template-guided growth of carbon nanotubes using anodized aluminum oxide nanopore templates provides vertically aligned, untangled planarized arrays of multiwall carbon nanotubes with Ohmic back contacts. Growth by catalytic chemical vapor deposition results in multiwall carbon nanotubes with uniform diameters and crystalline quality, but varying lengths. The nanotube lengths can be trimmed to uniform heights above the template surface using ultrasonic cutting, for example. The carbon nanotube site density can be controlled by controlling the catalyst site density. Control of the carbon nanotube site density enables various applications. For example, the highest possible site density is preferred for thermal interface materials, whereas, for field emission, significantly lower site densities are preferable.

### CROSS-REFERENCE TO RELATED APPLICATION

This application claims the benefit of U.S. Provisional Application No. 62/342,083, filed May 26, 2016, which is incorporated herein by reference.

### STATEMENT OF GOVERNMENT INTEREST

This invention was made with Government support under Contract No. DE-NA0003525 awarded by the United States Department of Energy/National Nuclear Security Administration. The Government has certain rights in the invention.

### FIELD OF THE INVENTION

The present invention relates to methods to grow carbon nanotube arrays and, in particular to methods that provide independent control of the crystalline quality of individual carbon nanotubes in a vertically-aligned array as well as control of the average spacing between such nanotubes in the array.

### BACKGROUND OF THE INVENTION

There are many potential applications for the use of vertically-aligned arrays of carbon nanotubes. A partial list includes thermal interface materials (TIMs), cold-cathode electron field emitters, and electrochemical sensors. Most applications are optimized when using the highest possible crystalline quality carbon nanotubes in the arrays, although the stringency of this requirement will vary depending on the application, or property of the nanotubes being used. In addition, different applications will perform best with different average spacing between the carbon nanotubes in an array. For example, the effectiveness of TIMs will increase with a greater number of individual thermal pathways in the array, hence, the highest possible nanotube site density is preferred. Conversely, field emission is optimized when there is a minimum separation between the nanotubes in an array, typically several times greater than the nanotube diameters. Hence, the site density for optimal field emission may be 5-100 times less than that for optimal TIMs.

For the purposes of discussing the materials problems and solutions to independently controlling the crystalline quality of the individual carbon nanotubes as well as their relative spacing within an array, the example of TIMs is used herein to: (a) motivate the importance of controlling these structural qualities; (b) identify critical materials issues; and (c) present robust solutions that are the subject matter of the present invention. Such control of structural properties is advantageous for other applications.

Removing heat generated by high-power electronics is often a limiting factor in device performance. As shown in FIG. 1, thermal interface materials (TIMs) may offer the advantage of simple, passive cooling for such devices. High-performance TIMs preferably have a high thermal conductivity, excellent adhesion and thermal bond to both the heat source (e.g., a Si chip) and the heat spreader/sink, thermal stability at the operating temperature, and negligible thermal stress (i.e., it does not delaminate).

Heat removal with existing TIMs is not good enough in many power electronics applications. For example, FIG. 2 shows a plot of the temperature rise with time of an insulated gate bipolar transistor (IGBT), which is a hot element in a typical photovoltaic inverter system. An 8 kW IGBT dissipates about 535 W of heat. Both temperature rise and device failure rate increase when low thermal conductivity TIM materials are used. Therefore, as shown in FIG. 3, device failure rates are a problem when the TIM thermal conductivity κ<20 W/m·K and become a serious problem when Λ˜1 W/m·K. Applications other than power electronics could also benefit from improved TIMs. These include, but are not inclusive of, solid-state lighting, high-power lasers, thermal batteries, and advanced batteries for electric and hybrid vehicles.

Conventional metal/epoxy composites (e.g., silver paste) provide excellent thermal contact, but typically exhibit poor thermal conductivity, suffer from thermal cycling degradation, and have poor adhesion quality. This is because the thermal conductivity of metal-filled epoxies is dominated by percolation through the epoxy, resulting in thermal conductivities of less than 1 W/m·K. Certain forms of carbon have very high thermal conductivity (e.g., diamond has a thermal conductivity of 90-2320 W/m·K and carbon nanotubes (CNTs) with high crystallinity can have conductivities as high as 3000 W/m·K). However, carbon-filled epoxies will have similar problems with percolation through the epoxy.

### SUMMARY OF THE INVENTION

The present invention is directed to the template-guided chemical vapor deposition (CVD) growth of carbon nanotubes using anodized aluminum oxide (AAO) nanopore templates. According to the present invention, vertically aligned, untangled planarized arrays of multiwall carbon nanotubes (MWNTs) with Ohmic back contacts can be grown in nanopore templates on arbitrary substrates. The templates can be prepared by sputter depositing Al films onto W-coated substrates, followed by anodization to form an aluminum oxide nanopore array. Small amounts of rare-earth metal doping in the Al, such as 2 wt. % Nd, can prevent the Al surface from prematurely oxidizing upon exposure to air prior to anodization. The substrate may be selected based on the desired properties for a given application since the tungsten underlayer provides the electrical access to the nanotubes. The tungsten underlayer helps eliminate the aluminum oxide barrier that typically occurs at the nanopore bottoms by instead forming a thin WO₃ layer. The WO₃ can be selectively etched to enable electrodeposition of metal catalysts in the nanopores, necessary to grow MWNTs, with control over the catalyst site density. Many materials have been reported as catalysts for the growth of MWNTs; the most commonly-used and preferred catalysts are Co, Ni, and Fe. Cobalt is used herein as an example. The deposited catalyst can be chemically etched to a predetermined recess level below the surface of the anodized aluminum oxide template layer. This etching enables control of the catalyst recess below the template surface. There exists a depth below the surface that will not reduce the carbon nanotube nucleation site density. Etching the catalyst to greater recesses below the AAO template surface will controllably reduce the carbon nanotube nucleation site density. Control of the carbon nanotube site density is relevant and different for various applications. For TIMS, the highest possible site density is preferred, however, for field emission, significantly lower site densities are preferable. Growth by catalytic chemical vapor deposition results in multiwall carbon nanotubes with uniform diameters and crystalline quality, but varying lengths. Therefore, the nanotube lengths can be trimmed to uniform heights above the template surface using ultrasonic cutting. The nanotube cutting technique retains Ohmic electrical contact between the nanotubes and the catalyst as well as to the tungsten underlayer, enabling whole-array electrical and thermal applications.

### BRIEF DESCRIPTION OF THE DRAWINGS

The detailed description will refer to the following drawings, wherein like elements are referred to by like numbers.

FIG. 1 is a schematic illustration of a power electronic device including a thermal interface material (TIM) between a heat source and a heat sink.

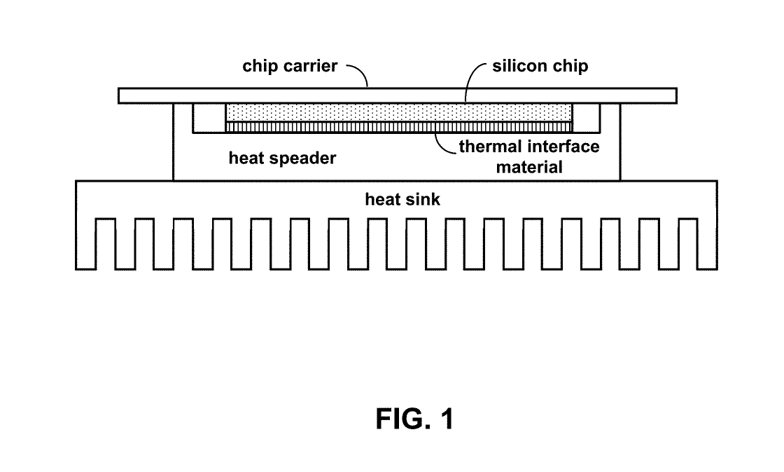

FIG. 2 is a plot of the temperature rise with time of an insulated gate bipolar device.

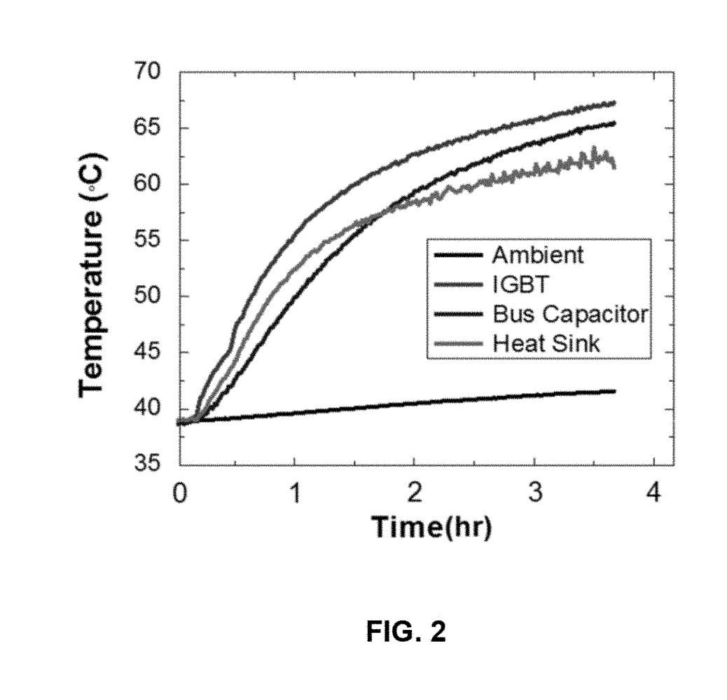

FIG. 3 is a graph of device failure rate as a function of TIM thermal conductivity.

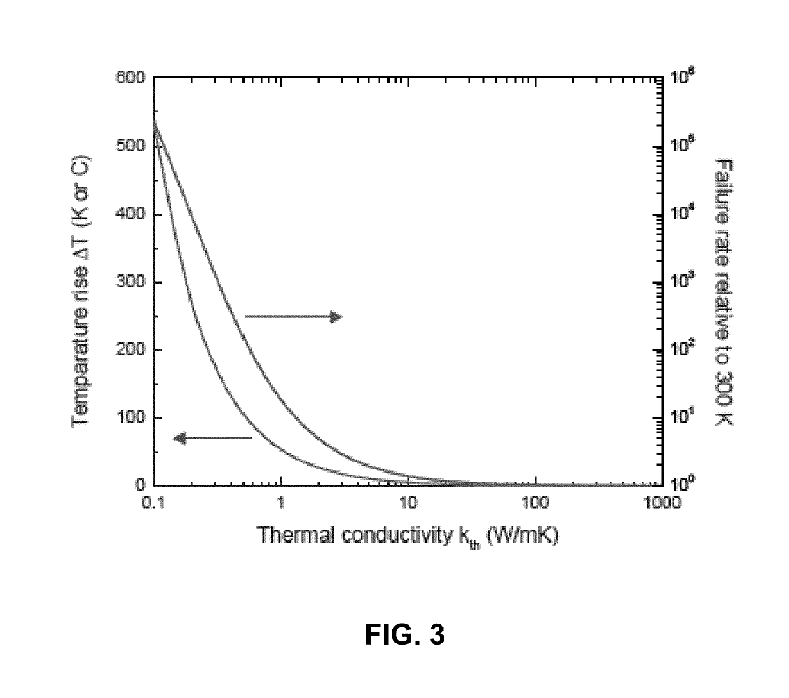

FIG. 4 is a schematic illustration of a carbon-nanotube-based TIM.

FIG. 5 is a graph of TIM thermal conductivity versus CNT thermal conductivity for various contact areas.

FIG. 6 is a schematic illustration of a TIM comprising carbon nanotubes grown in a nanopore template.

FIG. 7(a) is an SEM image of a test tube shaped pore structure and barrier oxide at the pore bottoms after anodizing an Al film without a W underlayer. The barrier oxide is marked with arrows. FIGS. 7(b)-(c) are SEM images of the tungsten/pore bottom interface before and after etching of the WO₃ plug, respectively. The arrows point to an example WO₃ plug and a resulting void after removal. All scale bars are 200 nm.

FIGS. 8(a)-(c) are representative SEM images of Co site density in ion milled pores for 10, 60, and 120 minute WO₃ etch times, respectively. Scale: pore diameter is 75 nm. FIG. 8(d) is a graph of Co site density versus WO₃ etch time. The line is a guide to the eye.

FIG. 9 is a schematic illustration of amorphous carbon deposits preventing MWNT growth.

FIGS. 10(a)-(c) are representative SEM images of MWNT arrays grown from Co metal catalysts that get progressively, albeit uncontrollably, closer to the AAO template surface.

FIG. 11(a) is an SEM image of the MWNT array overgrowth above the AAO surface. FIG. 11(b) is an SEM image of the MWNTs emerging from the AAO pore openings.

FIG. 12 is a graph of the Raman spectra of the MWNT array overgrowth above the AAO and an individual MWNT cut from the same array overgrowth by ultrasonication. Insets show SEM images of the material sampled for each spectrum.

FIGS. 13(a) and 13(b) are low and high magnification SEM images, respectively, of a MWNT array after ultrasonic cutting. The inset of FIG. 13(b) shows the ends of MWNTs before ultrasonic cutting.

FIG. 14(a) is a conductive AFM map of current between the top of the AAO/MWNT array and the underlying tungsten layer. FIG. 14(b) is a graph of I-V data from three individual MWNTs in the array showing Ohmic conduction through the MWNT, the MWNT-Co interface, and the Co-W interface after ultrasonic cutting.

FIG. 15 is an SEM image of a nanoporous AAO template after CVD carbon growth, showing pores blocked by amorphous carbon deposits.

FIG. 16 is an SEM image of a MWNT array resulting from the Co catalyst being made flush with the AAO template surface via ion beam milling.

### DETAILED DESCRIPTION OF THE INVENTION

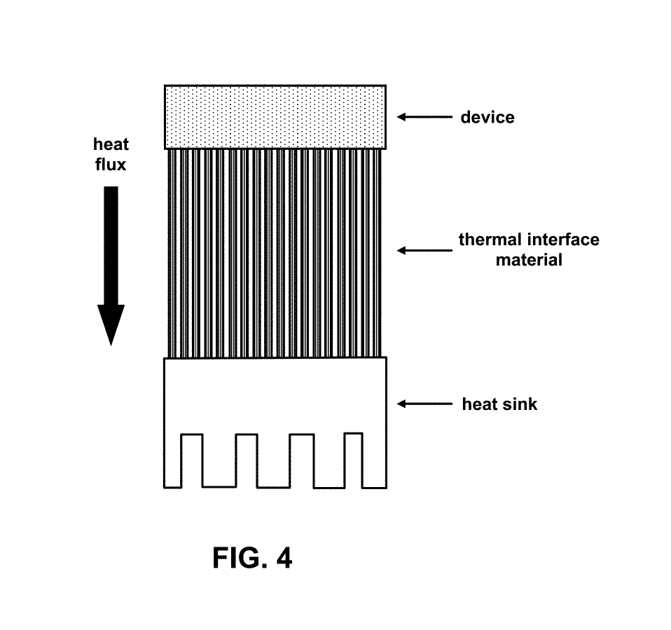

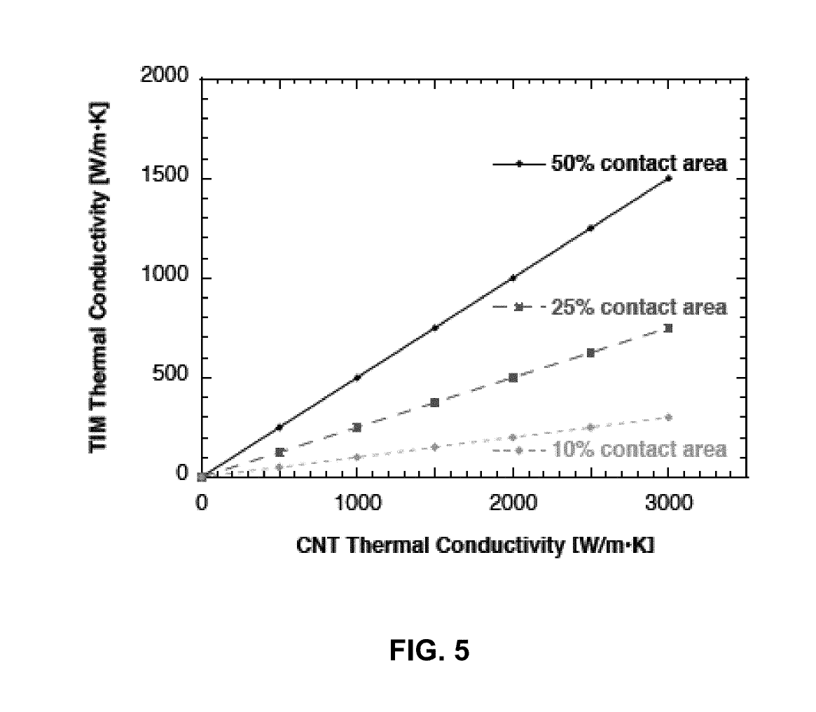

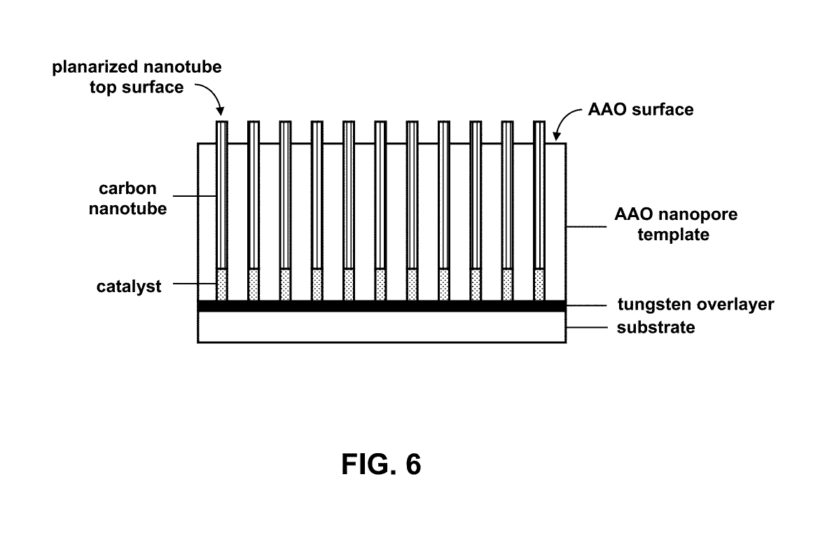

FIG. 4 shows an example of a carbon-nanotube-based TIM. The carbon-nanotube-based TIM has no epoxy in the thermal pathway, thereby enabling a high thermal conductivity and, therefore, high heat flux from a heat-generating device to a thermal spreader heat sink. FIG. 5 is a graph of the TIM thermal conductivity as a function of carbon nanotube (CNT) thermal conductivity for various contact areas. As can be seen, high quality CNTs can provide adequate TIM thermal conductivity, even with a low contact area. An optimal CNT-TIM preferably has no adhesives in the thermal pathway, a high CNT site density to increase the number of thermal pathways (i.e., no entanglement), planarized array tips to maximize thermal contacts to the hot device surface, and high-crystalline quality CNTs to provide a high thermal conductivity. As shown in FIG. 6, high density aligned arrays of CNTs can be grown using anodized aluminum oxide (AAO) nanopore templates on heat sink substrates (alternatively, arrays of CNTs can be grown on both sides of a substrate). High crystalline quality CNTs can be grown via thermal chemical vapor deposition (CVD). These CNTs can be grown directly on any substrate that will thermally survive the CNT growth temperatures. For TIMs applications, a preferred substrate is one with very high thermal conductivity that can be used as a heat sink. The intimate contacts between this heat sink material to the CNTs via thin tungsten and catalyst metals enables good thermal contact between the heat sink material to the very top of the CNT tips in the array. Finally, the top surfaces of the untangled CNTs can be planarized to a uniform height to enable good thermal contact to the heat source device.

Carbon nanotubes are highly regarded for their potential applications, particularly in electronics, due to their excellent electrical, thermal, and mechanical properties. The use of individual nanotubes as electronic components, such as transistors or interconnects, is the subject of many efforts, but significant challenges in selective placement and isolation of metallic or semiconducting nanotubes remain hurdles to large-scale use. Vertically aligned arrays of multiwall carbon nanotubes (MWNT), however, do not suffer from the same challenges and have been proposed as possible materials for a variety of applications, such as field emission, bio-sensors, and thermal interface materials. See Y. Saito and S. Uemura, Carbon 38, 169 (2000); S. Sotiropoulou and N. A. Chaniotakis, Anal. Bioanal. Chem. 375, 103 (2003); and J. Liu et al., Adv. Manuf. 1, 13 (2013). Aligned arrays of MWNTs have been fabricated by techniques such as thermal or plasma-enhanced chemical CVD, but the resulting MWNTs tend to suffer from one or more of the following drawbacks: entanglement, varying heights, lack of density control, and poor crystalline quality. See S. Fan et al., Science 283, 512 (1999); and Z. F. Ren et al., Science 282, 1105 (1998).

By employing an AAO template to guide nanotube growth, the diameter, length, and density of MWNTs can be controlled simply by tailoring the template geometry. This can be done by selecting the thickness of the Al film to be anodized, adjusting the anodizing conditions, and/or chemically widening the pores after anodization. Additionally, the physical constraint of the AAO template keeps the nanotubes from bundling or tangling together. If the nanotubes grow beyond the height of the template, they can be cut to uniform heights with ultrasonication or physical etching, such as ion milling or mechanical polishing. MWNTs have been grown in AAO templates in one of two ways. See S.-H. Jeong et al., Chem. Mater. 14, 1859 (2002). The first is by depositing amorphous carbon on the internal surfaces of the AAO template by high temperature pyrolysis of a carbon feed gas followed by a graphitization step. See J. Li et al., Appl. Phys. Lett. 75, 367 (1999); and J. S. Suh and J. S. Lee, Appl. Phys. Lett. 75, 2047 (1999). Such carbon tubes have poor crystallinity, do not extend above the AAO surface, and necessarily have identical diameter, length, and density to the AAO template pores. The second method is by CVD growth of MWNTs from catalyst stubs electrodeposited in the bottom of the AAO pores. See S.-H. Jeong et al., Appl. Phys. Lett. 78, 2052 (2001); S.-H. Jeong et al., Chem. Mater. 14, 4003 (2002); and G. P. Sklar et al., Nanotech. 16, 1265 (2005). Nanotubes resulting from the latter CVD process have higher as-grown crystalline quality, extend above the AAO surface, and have a MWNT site density which can vary between 0-100% of the template pores depending on template preparation and MWNT growth conditions. For these reasons, the catalyst-originated growth is preferred for applications of MWNT arrays as TIMs.

AAO templates for CVD growth of MWNTs are typically prepared by a two-step anodization of an electropolished Al sheet. This process results in a barrier oxide at the bottom of the pores that interferes with both the controlled electrodeposition into the pores and the quality of the electrical contact to the resulting MWNTs in the array. Additionally, the use of Al sheets limits possible applications if a different substrate is desired due to electrical or thermal conductivity requirements. Therefore, it is preferable to use AAO templates on substrates that provide control over the catalyst site density. Furthermore, Ohmic back contact to MWNTs grown from the pores can be achieved, even after ultrasonic cutting of the nanotubes. Therefore, this method provides a viable route for electrically or thermally active arrays of vertically aligned MWNTs on arbitrary substrates.

### Template and Catalyst Preparation

As an example, AAO templates were prepared on polished sapphire substrates. Templates prepared from films deposited on top of other substrates, such as silicon and aluminum, can also be prepared with an identical procedure. No differences in MWNT growth or template stability were found between arrays grown on the various substrates. A benefit of this method is that it can be applied to a variety of substrates that may be selected for their electrical and/or thermal properties, depending on the intended application. As an example, the sapphire substrate was first be coated with a 100 nm thick W film, followed by a 1-2.5 μm thick film of 2 wt. % Nd-doped Al, each deposited by RF magnetron sputtering. It is important to optimize sputtering conditions to minimize the residual film stresses and prevent the evolution of extremely rough surfaces or even film cracking and peeling. This can be done by measuring the curvature of a two-inch Si wafer before and after film deposition for a range of sputtering pressures and powers at a given sample to target spacing. See M. P. Siegal et al., Appl. Phys. Lett. 84, 5156 (2004). Furthermore, adhesion can be improved with the use of an ultrathin adhesion layer between the substrate and the W film. Titanium is commonly used as such an adhesion layer and need only be a few nanometers thick.

A rough surface is problematic for homogeneous template formation because the pores form perpendicularly to the local film surface. Using Nd-doped Al instead of pure Al further allows for a smooth, shiny surface, even after exposure to air. See J. Oh and C. V. Thompson, Adv. Mater. 20, 1368 (2008). Small amounts of other rare-earth metals (lanthanide series elements) are also known to reduce corrosion. These steps (stress reduction and Nd-doping) eliminate the need to electropolish the Al film or use a two-step anodization process. See S.-H. Jeong and K.-H. Lee, Synth. Met. 139, 385 (2003). After Nd-doped Al deposition, the films were removed from the chamber and one edge was masked off for sputter deposition of a 0.4 μm thick Ti strip to serve as an electrical contact for the anodization and electrochemical deposition of a catalyst.

The Nd-doped Al films can be anodized by known methods. See S. J. Limmer et al., J. Electrochem. Soc. 159, D235 (2012). In this example, the films were anodized at 40 V at 1° C. in a 3 wt. % oxalic acid solution agitated by bubbling air. A digital multimeter was used to log the current, which was terminated when the current dipped by ˜10-50% from its steady state value, indicating oxidation has reached the W underlayer. The resulting WO₃ layer was removed from the pore bottoms by soaking in a 0.2 M pH 7 phosphate buffer for 10-120 minutes, the latter etch time resulting in an electrically conductive bottom W contact to all of the nanopores. In this example, the pores were widened from ˜45 nm to ˜75 nm diameter by etching in 5 wt. % H₃PO₄ solution for 20 minutes at 30° C. Other acid electrolytes and anodization voltage combinations can provide controlled pore diameters ranging from 5 nm to 1 μm. Finally, a catalyst metal (cobalt) was deposited to the desired thickness from a bath of 1 M CoSO₄ and 0.4 M H₃BO₃ at −0.8 V versus Ag/AgCl with a Pt mesh counter electrode. Other metals, such as nickel and iron, and even silicon can be used as catalysts to support nanotube growth via CVD.

### Carbon Nanotube Growth and Characterization

After Co deposition, the AAO templates are ready for MWNT growth. As an example, nanotubes were grown by thermal CVD in a tube furnace at atmospheric pressure similar to processes reported for the growth of highly crystalline MWNTs on flat substrates. See M. P. Siegal et al., Appl. Phys. Lett. 80, 2171 (2002); and M. P. Siegal et al., J. Phys. Chem. C. 114, 14864 (2010). The furnace was ramped to 600° C. in a flowing mixture of 17% H₂ in N₂ with a total flow rate of 240 sccm. After ten minutes at 600° C., 20 sccm C₂H₂ was introduced to the existing gas flow. After 20 minutes, the H₂ and C₂H₂ were turned off, the N₂ flow was turned up to 2000 sccm, and the samples were furnace-cooled to room temperature before removal for characterization. The as-grown MWNT arrays were studied with scanning electron microscopy (SEM) and Raman spectroscopy.

### Nanotube Array Planarization and Characterization

The as-grown MWNT arrays can be cut to a relatively uniform height above the AAO surface by an ultrasonic cutting technique. See S.-H. Jeong et al., Chem. Mater. 14, 1859 (2002); and C. Rochford et al., J. Mater. Res. 30, 315 (2015). As an example, the as-grown sample with overgrown nanotubes protruding from the AAO was submerged in 5 mL of acetone in a 50 mL beaker and placed in a 40 kHz ultrasonic bath for one minute. This process cuts the MWNTs at a preferential height above the AAO surface and disperses the cut segments of the MWNTs in the acetone solution. The AAO/MWNT array was then rinsed with isopropanol and dried in flowing nitrogen. The cut MWNTs liberated into the solution were dip cast onto Si substrates for further analysis with Raman spectroscopy. The planarized MWNT array was examined with conductive atomic force microscopy (c-AFM). See I. Horcas et al., Rev. Sci. Inst. 78, 013705 (2007).

### WO₃ Etch and Co Site Density

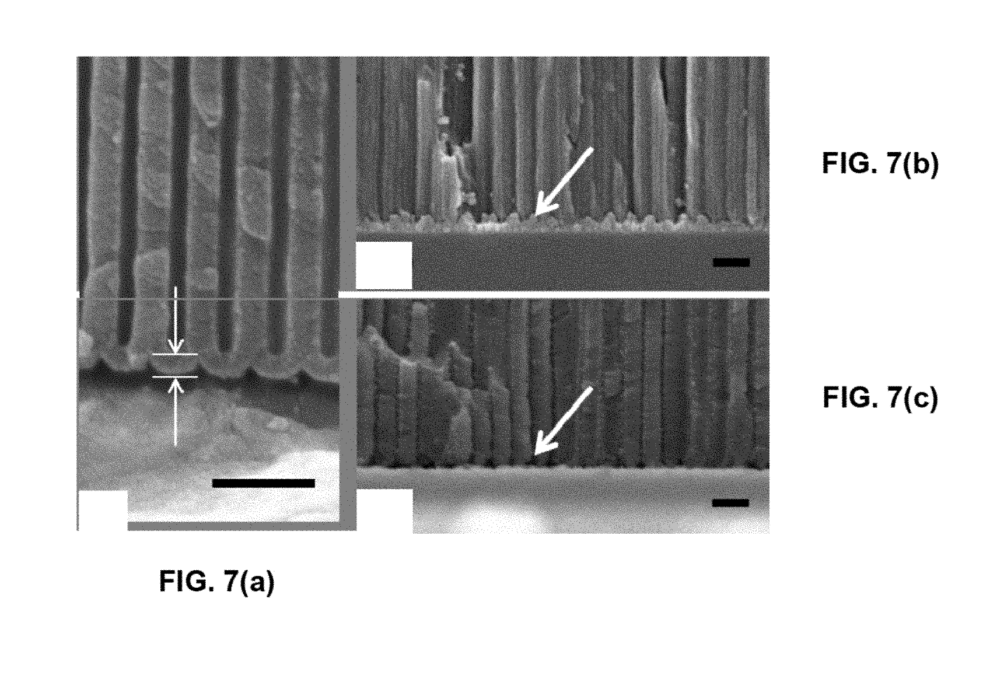

In order to grow an array of MWNTs in AAO with maximum site density, it is preferable start with near 100% Co site density, i.e. a carbon nanotube will not nucleate and grow without the presence of a good catalyst in the nanopore. The key to achieving this is the W underlayer. When Al is anodized it results in a test-tube-like structure with a barrier oxide thickness similar to the sidewall thickness at the bottom of the pores above the underlying substrate or un-anodized metallic aluminum, as marked with arrows in FIG. 7(a). To successfully electrodeposit catalysts at the pore bottoms, this barrier oxide should be as thin and uniform as possible. For MWNT array applications, this is normally achieved via barrier thinning, by decreasing the applied anodization voltage and a pore-widening step, if desired. See G. P. Sklar et al., Nanotech. 16, 1265 (2005). If an underlayer is used that oxidizes under the same conditions as the Al film and has a higher ionic conductivity than alumina, as tungsten does, the underlayer's oxide will grow into the pore and form an oxide plug. See J. Oh and C. V. Thompson, Adv. Mater. 20, 1368 (2008); and S. J. Limmer et al., J. Electrochem. Soc. 159, D235 (2012). This is shown in FIG. 7(b), where the arrow points to one such WO₃ plug. By selectively etching the WO₃ plug, the underlying metallic W can be exposed at the pore bottoms, as shown in FIG. 7(c). This metallic W underlayer facilitates electrodeposition of the Co catalyst and provides a backside electrical contact, even on an insulating substrate.

To investigate the catalyst site density resulting from the W underlayer technique, ˜750 nm Co was electrodeposited into the pores followed by ion milling of the AAO surface. A Co height of 750 nm was determined to yield reliable MWNT growth for the given nanopore depths. The ion milling, which etches a wide-angle cone as the sample rotates, continues until the AAO in the center of the cone is completely removed. In this configuration, SEM can easily distinguish between the filled and empty pores along the etched cone since the surface of the AAO and the Co nanowires are now flush with each other. The Co-containing pores will appear bright relative to the empty pores. Furthermore, the height uniformity of the Co nanowires can be demonstrated by comparing the fraction of full and empty appearing pores as the pores are imaged radially out from the center of the etched cone.

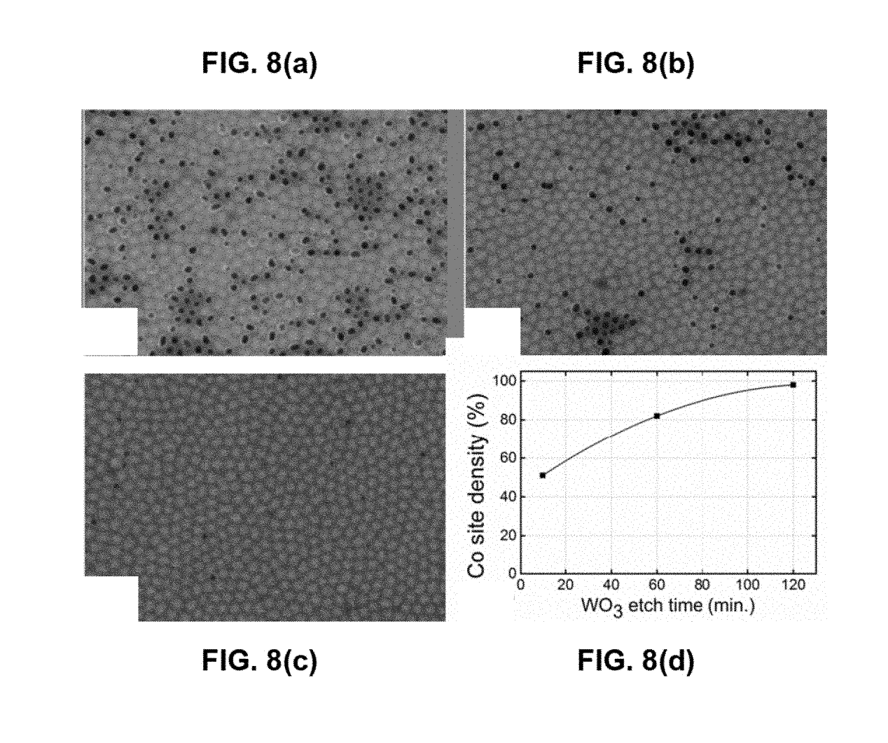

For a given distance from the etched cone center, the apparent pore filling ratio is constant. SEM images in this regime for WO₃ etch times of 10, 60, and 120 minutes are shown in FIGS. 8(a)-(c). Etch times longer than 120 minutes and up to 15 hours yield no further improvement or template failure upon Co electrodeposition. As shown in FIG. 8(a), the 10 minute etch time leaves both empty isolated pores surrounded by full pores as well as clusters of empty pores. Increasing the etch time to 60 minutes decreases the number of clusters and the total number of empty pores, as shown in FIG. 8(b). After 120 minutes, all empty pore clusters are eliminated, with only a few isolated empty pores remaining, as shown in FIG. 8(c). FIG. 8(d) shows the Co site density as calculated from representative SEM images for each of the three WO₃ etch times. With this technique, the upper limit of Co site density is ˜98%. Controlling the WO₃ etch time, therefore, provides a technique to tune the site density of the Co catalyst and thus that of the MWNTs. This approach is also relevant for controlling the fabrication of nanowire arrays of other materials using AAO templates.

### Carbon Nanotube Growth and Characterization

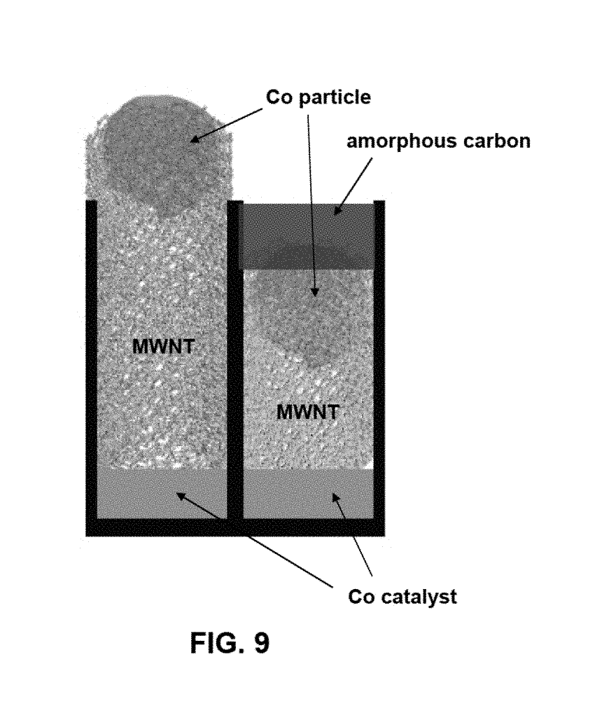

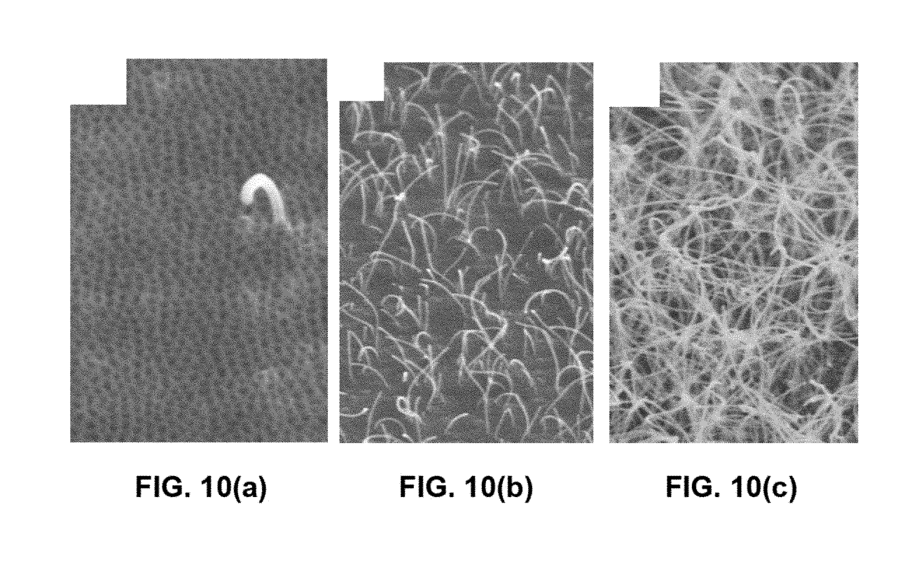

When C₂H₂ is introduced to the CVD furnace at temperature, there are two competing processes: (1) CVD growth of carbon nanotubes from the Co catalyst and (2) amorphous carbon deposition via C₂H₂ decomposition on the AAO surfaces. See P.-L. Chen et al., Appl. Phys. Lett. 86, 123111 (2005); and J. S. Lee et al., Chem. Mater. 13, 2387 (2001). Catalytic CVD growth of MWNTs from Co under experimentally similar conditions is known to occur by tip growth, as opposed to base growth, as evidenced by transmission electron microscopy imaging of Co particles at the ends of MWNTs which emerge from the pores. See P.-L. Chen et al., Appl. Phys. Lett. 86, 123111 (2005). However, as the amorphous carbon deposits on the pore walls, it can prevent upward lifting of the Co catalyst, halting MWNT growth and leaving short MWNTs inside the pores, as shown in FIG. 9. MWNTs that do emerge from the pore openings are free to continue growing longer with time. Adding H₂ to the gas mixture during nanotube growth has been systematically shown to etch away amorphous carbon and help MWNTs emerge from the pores. See P.-L. Chen et al., Appl. Phys. Lett. 86, 123111 (2005). In addition to blocking the Co particle uplift, if the concentration of the carbonaceous feed gas is too high the Co catalyst can be deactivated by amorphous carbon deposition. This results in shorter MWNTs above the AAO surface at which point amorphous carbon growth on the AAO is no longer interfering with the MWNT growth. Decreasing the aspect ratio of the open pore above the Co catalyst is another technique to increase the fraction of pores producing MWNTs. Varying the aspect ratio by more than a factor of 4 was shown to vary the emerging MWNT density by 4 orders of magnitude, underscoring the sensitivity of this competition. See S.-H. Jeong et al., Chem. Mater. 14, 4003 (2002). This is demonstrated as well in FIGS. 10(a)-(c) that show increasing MWNT site densities. This is a result of electrochemically depositing the Co into the nanopores to different levels below the AAO template surface. However, it is extremely difficult, if not impossible, to control the level of Co in the nanopores using electrochemical deposition. Several reasons exist for this, all leading to the fact that some pores will fill with Co faster than others. Once the first pores overfill and begin to plate directly onto the AAO template surface, further deposition into the remaining pores is terminated as the Co will deposit based on the path of least resistance, or in this case, now directly on the template surface.

All of these mechanisms are relevant. The presence of amorphous carbon on the AAO surface was confirmed by Raman spectroscopy of an AAO template that underwent an identical CVD process without the Co catalyst. Additionally, a maximum aspect ratio ˜10 was established as necessary for at least 1% emerging MWNT site density as determined by SEM imaging. Explicitly stated, for a pore diameter of 75 nm, the depth of the open pore above the Co needs to be less than 750 nm for MWNTs to emerge from the pores. Because the aluminum film expands by nearly 50% upon anodization, a deposited one micron thick Al film produces a 1.5 μm thick AAO template and requires electrodeposition of 750 nm of Co. However, as noted above, this level of control in every nanopore is not reproducible using electrochemical deposition.

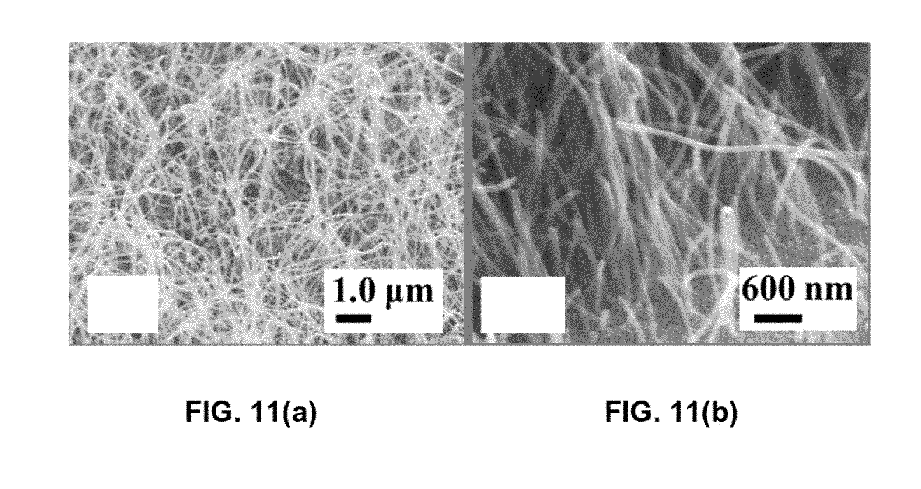

SEM images of the as-grown MWNT arrays are shown in FIGS. 11(a)-(b). Once the MWNTs emerge from the pore openings they lose their lateral confinement and tend to take random gently curved paths resulting in a loosely intertwined network of MWNTs. However, the growth is generally free from kinks and bends, which would be evidence of severe microstructural defects in the nanotubes. FIG. 11(b) provides a magnified inspection near the AAO surface and reveals that MWNTs emerge from the pores straight and with uniform diameter, however not every pore yields a nanotube. With further optimization of the gas composition and pore aspect ratio, higher MWNT site density can be achieved. The MWNT diameter appears to be slightly larger than the pore opening, in agreement with previous reports. See S.-H. Jeong et al., Chem. Mater. 14, 1859 (2002); and J. S. Suh and J. S. Lee, Appl. Phys. Lett. 75, 2047 (1999).

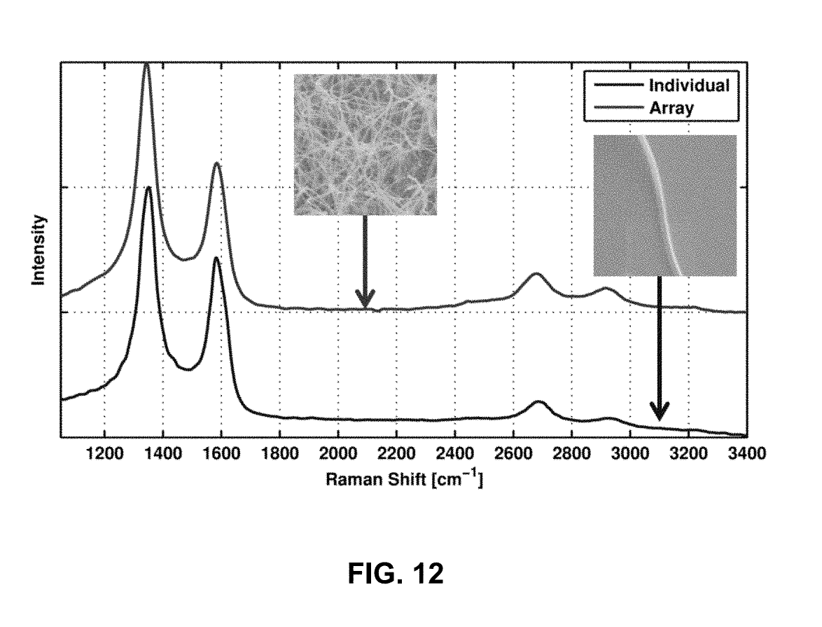

To gain insight into the MWNT crystalline quality resulting from this template growth process, Raman spectra were acquired on: (1) the overgrown array and (2) an individual tube dispersed on a silicon substrate after being sheared from the template during sonication. In order to obtain a representative sample, 200 separate spectral acquisitions of the overgrown array were gathered over a length scale of 100 μm. Since the AAO has a nominal pore size of 75 nm and the diameter of the Raman spot is ˜350 nm, the average spectrum for an array shown in FIG. 12 resulting from these 200 acquisitions is the composite signal resulting from a sample of ˜1,000 separate MWNTs. No appreciable change in the Raman signal was observed between any of the 200 acquisitions. In a similar fashion, investigation of an individual MWNT occurred via spectral acquisition every 30 nm over 2×3 μm area. Little variation was observed over the 500 Raman spectra acquired across the nanotube. In addition, little variation occurred from tube to tube. Spectra similar to that shown in FIG. 12 were acquired on 10 separately imaged individual MWNTs. Therefore, the average response shown in FIG. 12 is representative of the individual MWNT as a whole.

The Raman response of both the array and individual tube are marked by four distinct spectral features characteristic of MWNTs, namely the 1^{st} order D-(˜1350 cm⁻¹) and G-modes (1582 cm⁻¹) along with the 2^{nd} order 2D-(˜2677 cm⁻¹) and D+G (2930 cm⁻¹) modes. See M. S. Dresselhaus and P. C. Eklund, Adv. Phys. 49, 705 (2000). While observation of the D and D+G modes is indicative of crystalline disorder, the persistence of the 2D-mode accompanied by an I(D)/I(G) ratio of 1.9 implies that this disorder is moderate and in line with previous reports of non-graphitized CVD-synthesized MWNT arrays grown without the use of templates. See H. S. Kang et al., Chem. Phys. Lett. 349, 196 (2001); N. Halonen et al., Phys. Status Solidi B. 248, 2500 (2011); Y. Joon Yoon et al., Chem. Phys. Lett. 366, 109 (2002); and M. Chen et al., J. Mater. Sci. 37, 3561 (2002). Due to this similarity with reported non-templated growth, it can be concluded that the use of the AAO template is to first order benign to the synthesis of the MWNTs. Furthermore, since the Raman spectrum of an individual tube is very similar to that acquired over an array of tubes, the template approach results in nominally uniform MWNTs across the array. The MWNT crystalline quality can be improved with a post-growth graphitization annealing step. See D. Mattia et al., J. Phys. Chem. B 110, 9850 (2006); and W. Huang et al., Carbon 41 2585 (2003).

### Nanotube Array Planarization and Characterization

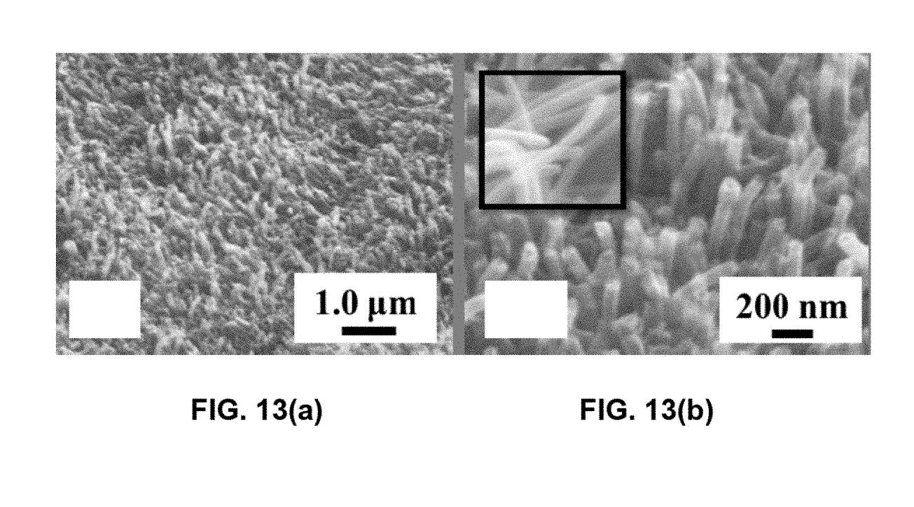

FIGS. 13(a)-(b) show SEM images of the MWNT array in AAO after ultrasonication in acetone for one minute, after which nearly every nanotube is cut to a few hundred nanometers above the AAO surface. For illustration purposes, a region with higher than average MWNT site density is shown. Because of the sensitivity of the MWNT density to the factors described above, some variation can be observed across a given sample. The MWNTs do not fully support each other laterally, since their site density has yet to be optimized, and they tend to clump together or lean over. This can be improved by drying the array in supercritical CO₂. See Y. Liang et al., J. Am. Chem. Soc. 126 16338 (2004); and S. J. Limmer et al., Nano Lett. 14, 1927 (2014). FIG. 13(b) shows a higher magnification image of the ends of the cut MWNTs. The insert shows an image of the MWNT ends before cutting. By comparison, it is clear that the growth produces carbon nanotubes and that ultrasonication results in open ended tubes.

However, there is an open question remaining as to whether or not ultrasonication degrades or destroys the electrical contact between the MWNT, the Co catalyst, the W-coated substrate, or even causes breaks in the MWNTs themselves inside the template. To answer this question, c-AFM was employed to study the current path between the exposed MWNT tip and the W underlayer. For this measurement, contact to the W underlayer was made through the Ti strip that is located on one edge of the sample surface as mentioned above. The Ti strip makes contact with the W underlayer through the non-anodized Nd-doped Al that is under the strip. The W underlayer extends across the entire substrate and makes contact with every Co catalyst nanowire. Topological and current maps can be acquired simultaneously in non-contact/intermittent mode using a conductive tip with a nominal spring constant of 18 N/m. Non-contact mode is necessary due to mechanical damage and nanotube cleaving produced by physical contact between the tip and the MWNT. The tip will, however, have momentary contact with protruding MWNTs on the side of approach before the feedback is able to move the tip over the MWNT.

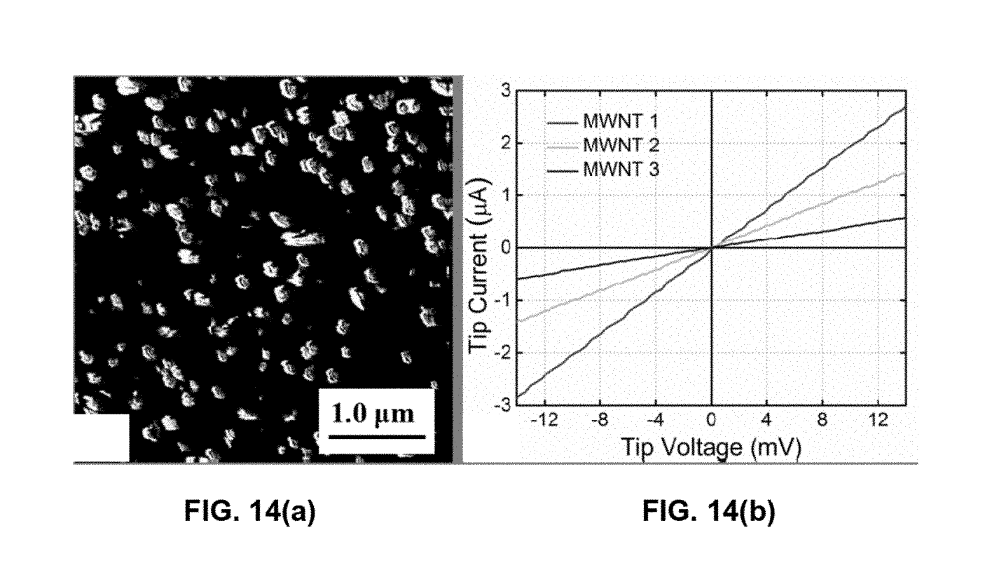

FIG. 14(a) shows a current map generated by c-AFM. During current mapping, a static bias voltage is applied to the tip, and the current through the sample is recorded as a function of tip position. Current is only detected when the tip is in intermittent contact with a MWNT. As expected, no current is seen from the AAO itself. Intermittent contact occurs when the non-contact topological feedback begins to move the tip over a MWNT. Since the non-contact feedback is not perfect, there are brief moments when the tip touches the MWNT. This is verified by merging both the topological and current maps (not shown) to reveal that the current flow occurred at the approaching edge of the MWNT.

FIG. 14(b) shows I(V) data collected on three individual MWNTs in contact mode with a loading force of ˜1.6 μN using the same tip as the non-contact imaging experiments. The electrical resistance varies from ˜5-25 kΩ, depending on the MWNT being measured. This resistance includes the series resistance contributions of the Nd-doped Al, W, and Co, as well as the contact between the metal layers, the contact between the Co and MWNT, and the contact between the MWNT and the tip. In every case, Ohmic I(V) behavior is observed, implying that the W-Co and Co-MWNT interfaces have not been seriously compromised. This measurement does not explain the origin of the range of total resistance measured, but the contact resistance and contact geometries between individual MWNTs and the c-AFM tip are potential sources of variability. It is also not known how many shells of a MWNT contribute to the electronic conduction for each measurement and hence how many parallel current paths through the MWNT are in use. The MWNTs are open at the c-AFM tip end, suggesting that the tip could be in contact with several shells at once. However, if the tip is only in contact with the outermost shell, for instance from a MWNT edge, only that shell would contribute significantly to the conductivity since adjacent shells have negligible inter-layer electronic coupling. See P. G. Collins et al., Science 292, 706 (2001).

Ohmic contact between the MWNTs and the underlying metal is significant. One of the benefits of the W underlayer technique discussed above is the ability to have electrical contact to the entire MWNT array regardless of the chosen substrate's electrical properties. This offers flexibility in device design not possible when MWNT/AAO arrays are fabricated from Al sheets. Confirming the retention of Ohmic contact to the MWNTs after ultrasonic cutting allows for a simple, scalable technique to cut all MWNTs in the array to a uniform height. Good electrical conductivity from the MWNT tip to the substrate surface is critical for electronic applications using the array, such as field emission or electrochemical sensing. Furthermore, such good electrical conductivity from the MWNT tip to the substrate surface also suggests the possibility of good thermal conductivity, i.e., the conducting pathways do not appear to be damaged or broken from the ultrasonication process.

### Carbon Nanotube Growth from Controlled Recess Catalyst

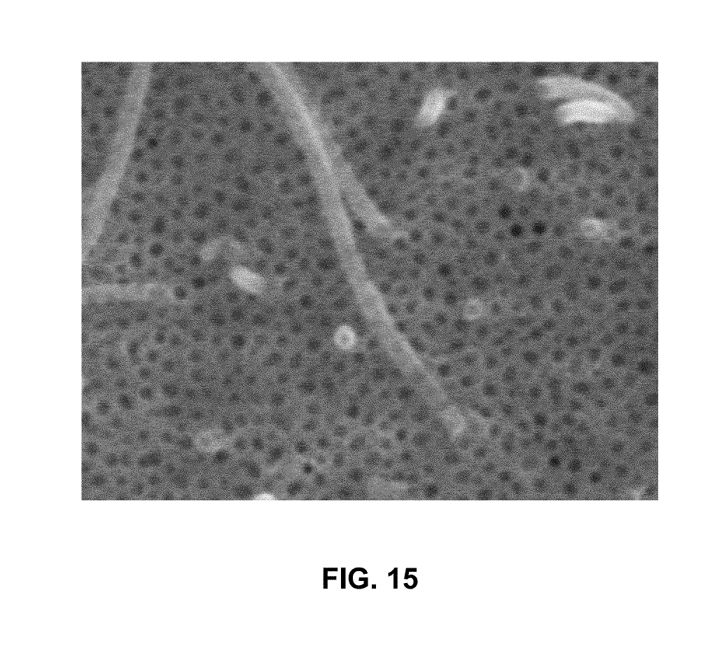

As described above, the AAO catalyzes C₂H₂ decomposition that can plug the pore openings with amorphous carbon, thereby preventing the emergence of MWNTs. This can be seen in FIG. 15, which is a top-view SEM image of an AAO template after CVD carbon growth. Many of the nanopores are dull gray, indicating pores that are filled with amorphous carbon, which prevents the MWNTs from growing up and out of the pores. The competition between amorphous and MWNT growth suggests a need for a short distance between the top of the catalyst and the template surface, i.e., small aspect ratios. Therefore, the smaller the aspect ratio of open pore space the better. Unfortunately, the precise filling of the pores is very difficult to control via the electrochemical deposition of Co into the nanopores using the method described above.

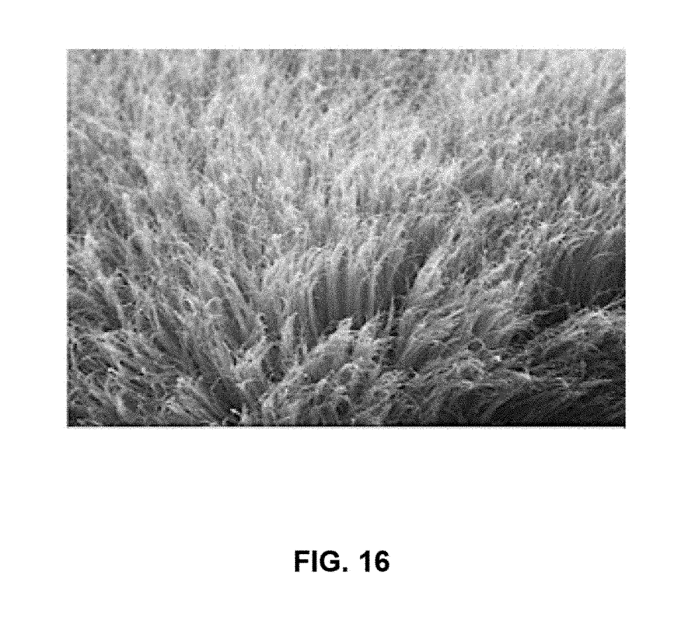

In fact, best results have been obtained with zero aspect ratio, wherein the Co catalyst is flush with the template surface. For example, the catalyst can be deposited as close as possible to the template surface, preferably without excessive overflowing onto the template surface, and ion beam milling can be used to make the surface flush. This results in the highest possible carbon nanotube site density, with essentially 100% of the pores supporting MWNT growth. This is shown in FIG. 16, which is a top-view SEM image of an array of MWNTs grown on such an ion beam milled surface where the Co catalysts became flush with the template surface. This result has many attributes. First, the individual MWNTs are not tangled together. This is because they were grown using thermal CVD, which results in high crystalline quality MWNTs. Such good crystalline quality reduces the presence of defects within the individual MWNTs such that they grow without kinks and bends. The minimization of such defects fundamentally decreases phonon scattering sites within a MWNT, enabling the highest possible thermal conductivity. Conversely, the more commonly used plasma enhanced CVD methods for the growth of MWNTs is kinetically driven, resulting in higher growth rates. It is well known that crystals produced at higher growth rates are more likely to incorporate greater defect densities. In the case of MWNTs, such defects lead to commonly observed kinks and bends.

Second, the absence of kinks and bends also prevents the MWNTs from entangling with one another. Such entanglement sterically reduces the density of MWNTs that can reach to a given growth height. This is analogous to filling space more efficiently with straight tubes, rather than bent and curly tubes that are all different from one another. The nearly complete nucleation from the Co catalysts can lead to filling >40% of the volumetric space in the array with 75 nm diameter MWNTs. This fraction would increase using smaller diameter MWNTs grown in smaller diameter AAO template pores. For example, if the more commonly used plasma enhanced CVD methods were used to grow MWNTs, the resulting kinks and bends in the MWNTs sterically prevent the efficient filling of volumetric space. Such methods typically result in achieving MWNT volumetric fill factors of only a few percent.

As described above, ultrasonication can be used to cut all the MWNTs to roughly the same height above the template surface. This height uniformity is critical to being able to allow every MWNT tip to make contact with the heat source surface to be cooled. Furthermore, this is also relevant for electronic applications such as field emission and electrochemical sensing, where the MWNT tip heights needs to be as homogeneous as possible for large area uniform operation. However, this ultrasonication process will not work if the CNTs grow directly from what is basically a Co-catalyst dot on the template surface. With nothing holding the MWNTs mechanically to the substrate, ultrasonication will essentially remove all the MWNTs from the substrate.

Alternatively, the nanopores can be filled with Co catalyst, polished to make the catalyst essentially flush with the template surface via ion beam milling or some other planarization method, and then the catalyst can subsequently be chemically etched to a controlled, predetermined level below the nanopore template surface. This enables control of the catalyst recess below the template surface to levels that will not reduce the carbon nanotube nucleation site density, or to controlled levels below a critical point that control the nucleation site density for other applications. The recessed catalyst also provides a mechanical ‘grab’ to hold the MWNT in place during the ultrasonication cutting process.

The present invention has been described as method to fabricate high crystalline quality carbon nanotubes with controlled nucleation site densities for vertically aligned arrays. The concept of a carbon-nanotube-based thermal interface material for power electronics was used to illustrate the materials issues and solutions necessary to controlling the qualities of such structures. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A method for growing arrays of carbon nanotubes, comprising:
providing an anodized aluminum oxide template comprising a plurality of nanopores on a substrate having an electrically conductive surface,
electrodepositing a catalyst metal on the electrically conductive substrate in the bottom of at least some of the nanopores, and
growing a carbon nanotube on the catalyst metal in at least some of the nanopores.

2. The method of claim 1, wherein the electrically conductive surface comprises tungsten.

3. The method of claim 1, wherein the catalyst metal comprises cobalt, nickel, or iron.

4. The method of claim 1, wherein the providing an anodized aluminum oxide template comprising a plurality of nanopores on a substrate having an electrically conductive surface comprises:
depositing a rare-earth-doped aluminum film onto a tungsten-coated substrate,
anodizing the rare-earth-doped aluminum film, thereby forming a plurality of nanopores and leaving tungsten oxide on the tungsten-coated substrate at the bottom of the plurality of nanopores; and
removing tungsten oxide from the bottom of at least some of the plurality of nanopores, leaving an electrically conductive tungsten surface in the bottom of the at least some of the plurality of nanopores.

5. The method of claim 4, wherein the removing tungsten oxide comprises soaking the anodized rare-earth-doped aluminum film in a phosphate buffer for a predetermined etch time to provide the electrically conductive tungsten surface in the bottom of the at least some of the plurality of nanopores, thereby providing a desired catalyst metal site density.

6. The method of claim 1, further comprising widening the plurality of nanopores by chemical etching prior to electrodepositing the catalyst metal.

7. The method of claim 1, further comprising planarizing the grown carbon nanotubes to a uniform height above the top surface of the template by ultrasonic cutting.

8. The method of claim 1, further comprising planarizing the grown carbon nanotubes to a uniform height above the top surface of the template by ion milling or mechanical polishing

9. The method of claim 1, wherein the growing a carbon nanotube comprises catalytic chemical vapor deposition.

10. The method of claim 1, wherein the electrically conductive substrate comprises an electrically conductive coating on a sapphire, silicon, or aluminum substrate.

11. The method of claim 1, wherein the aspect ratio of the plurality of nanopores is less than 10.

12. The method of claim 1, comprising electrodepositing the catalyst metal to overfill the nanopores, planarizing the catalyst metal to be flush with the top surface of the template, and etching the catalyst metal to a controlled recess level below the top surface of the template.

13. The method of claim 1, wherein the diameter of the plurality of nanopores is less than 1 micron.
